(19) United States
(12) Patent Application Publication
(10) Pub. No.: US 2003/0001621 A1
(43) Pub. Date: Jan. 2, 2003

(54) Data I/O circuit of semiconductor memory device

(76) Inventors: Se Jun Kim, Kyoungki-do (KR); Jae Kyung, Seoul (KR)

Correspondence Address: JACOBSON HOLMAN PLLC, 400 SEVENTH STREET N.W., SUITE 600, WASHINGTON, DC, 20004, US

(21) Appl. No.: 10/136,306

(22) Filed: May 2, 2002

(30) Foreign Application Priority Data
Jun. 29, 2001 (KR) 2001-38033

(51) Int. Cl. H03K 19/00

(52) U.S. Cl. 326/93

(57) ABSTRACT

A data I/O circuit of a semiconductor memory device employing clock synthesizing means for inputting synthesized clock signals of clock signals of two nodes of a metal line transmitting the clock signals to the corresponding data buffer in order to decrease a time difference of the clock signals for driving the plurality of data buffers. As a result, the data I/O circuit of a semiconductor memory device performs an operation of the semiconductor memory device at a high speed by reducing a data setup/hold time, by equalizing an enable time of a plurality of data buffers.

### BACKGROUND OF THE INVENTION

1. Field of the Invention

The present invention relates to a data I/O (input/output) circuit for a semiconductor memory device, and in particular to an improved data I/O circuit for a semiconductor memory device which can perform operations at a high speed by means of a method of reducing data setup/hold time by equalizing the enable time of a plurality of data buffers.

2. Description of the Background Art

FIG. 1 is a block diagram illustrating a conventional data I/O circuit of a semiconductor memory device.

The conventional data I/O circuit includes: a clock synchronization unit 1 for synchronizing an internal clock signal ICLK with an external clock signal ECLK by using a delay locked loop DLL or a phase locked loop PLL; a clock driving unit 2 for transferring the internal clock signal ICLK to a clock signal transmission line (metal line) CL; a memory block 3 for storing data; a plurality of data buffers DBUF0-DBUF15 for buffering the data according to the internal clock signal ICLK; and a plurality of data pads DQ0-DQ15 for outputting the data from the data buffers DBUF0-DBUF15 or externally receiving data.

The operation of the conventional data I/O circuit is described with reference to a timing diagram of FIG. 2.

Initially, the clock synchronization unit 1 synchronizes the internal clock signal ICLK with the external clock signal ECLK.

The internal clock signal ICLK is transmitted to the data buffers DBUF0-DBUF15 through the clock signal transmission line CL made of metal. Here, the clock driving unit 2 is employed to drive the internal clock signal ICLK in order to prevent delay of the internal clock signal ICLK.

As illustrated in FIG. 2, the internal clock signals C7, C8 inputted to the data buffers DBUF7 and DBUF8 closest to the clock driving unit 2 are delayed as long as the internal clock signal ICLK. However, the internal clock signals C0 and C15 inputted to the data buffers DBUF0 and DBUF15 farthest from the clock driving unit 2 are delayed longer than the internal clock signal ICLK by a delay time DT.

Accordingly, there is a time difference DT between the data output timing of the data buffers DBUF7 and DBUF8 closest to the clock driving unit 2 and a data output timing of the data buffers DBUF0 and DBUF15 farthest from the clock driving unit 2, thereby generating a data error.

The data setup/hold time should be increased to prevent the data error. However, the increased data setup/hold time decreases operation speed of the semiconductor memory device.

### SUMMARY OF THE INVENTION

Accordingly, it is an object of the present invention to provide a data I/O circuit of a semiconductor memory device which can perform operations at a high speed by means of a method of outputting clock signals having an identical timing to a plurality of data buffers, by connecting a clock synthesizing means to a clock signal transmission line.

In order to achieve the above-described object of the invention, there is provided a data I/O circuit of a semiconductor memory device, including: a memory means for storing data; a clock synchronization means for synchronizing an internal clock signal with an external clock signal; a clock driving means for driving the internal clock signal; a clock signal transmission line wherein the internal clock signal is transmitted; a plurality of clock synthesizing means for synthesizing clock signals of corresponding nodes of the clock signal transmission line; a plurality of data buffers for buffering data according to the clock signals from the plurality of clock synthesizing means; and a plurality of data pads for externally outputting the data from the plurality of data buffers, or externally receiving data.

### BRIEF DESCRIPTION OF THE DRAWINGS

The present invention will become better understood with reference to the accompanying drawings which are given only by way of illustration and thus are not limitative of the present invention, wherein:

FIG. 1 is a block diagram illustrating a conventional data I/O circuit of a semiconductor memory device;

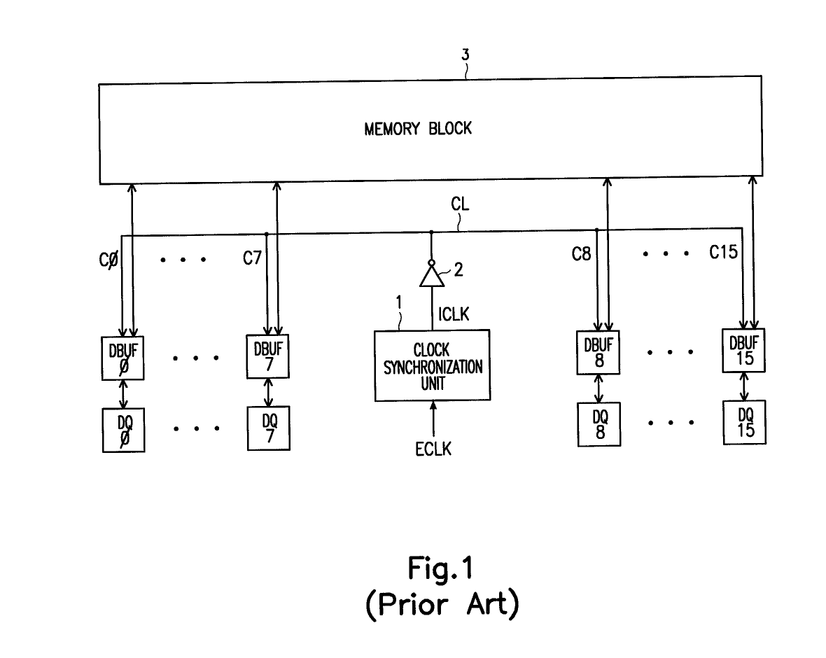

FIG. 2 is a timing diagram showing delay of clock signals for the data I/O circuit in FIG. 1;

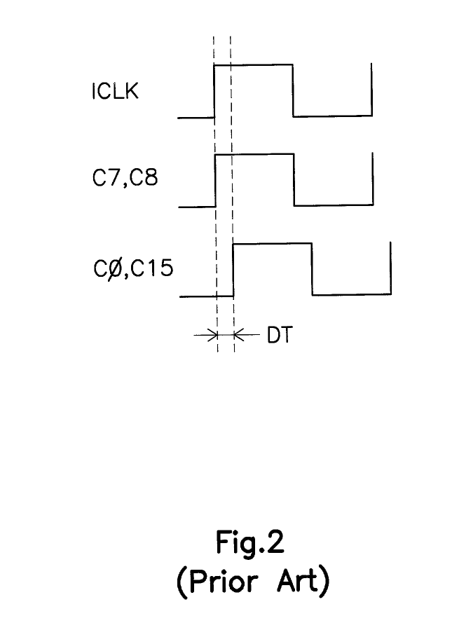

FIG. 3 is a block diagram illustrating a data I/O circuit of a semiconductor memory device in accordance with a first embodiment of the present invention;

FIG. 4 is a detailed circuit diagram illustrating a clock synthesizing unit of FIG. 3;

FIG. 5 is a timing diagram showing delay of clock signals for the data I/O circuit in FIG. 3; and

FIG. 6 is a block diagram illustrating a data I/O circuit of a semiconductor memory device in accordance with a second embodiment of the present invention.

### DETAILED DESCRIPTION OF THE PREFERRED EMBODIMENTS

A data I/O circuit of a semiconductor memory device in accordance with preferred embodiments of the present invention will now be described in detail with reference to the accompanying drawings.

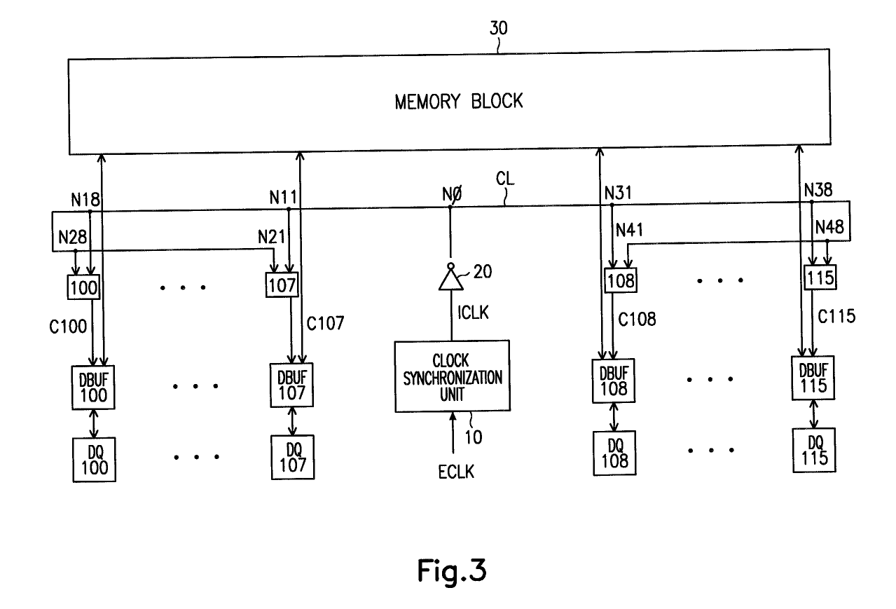

FIG. 3 is a block diagram illustrating a data I/O circuit of a semiconductor memory device in accordance with a first embodiment of the present invention.

The data I/O circuit includes: a clock synchronization unit 10 for synchronizing an internal clock signal ICLK with an external clock signal ECLK; a clock driving unit 20 for transferring the internal clock signal ICLK to a clock signal transmission line CL; a plurality of clock synthesizing units 100-115 for synthesizing the internal clock signals of corresponding nodes N11-N18, N21-N28, N31-N38 and N41-N48 in the clock signal transmission line CL and outputting clock signals C100-115; a plurality of data buffers DBUF10-DBUF115 for buffering data according to the synthesized clock signals C100-C115; and a plurality of data pads DQ100-DQ115 for externally outputting the data from the plurality of data buffers DBUF100-DBUF115, or receiving data from external devices.

At this time, the clock signal transmission line CL is connected at a node NO to the clock driving unit 20 and at nodes N11˜N18, N21˜N28, N31˜N38, and N41˜N48 to the plurality of clock synthesizing units 100˜115 to a node NO to which the clock driving unit 20 is connected.

The clock synchronization unit 10 consists of a delay locked loop or a phase locked loop.

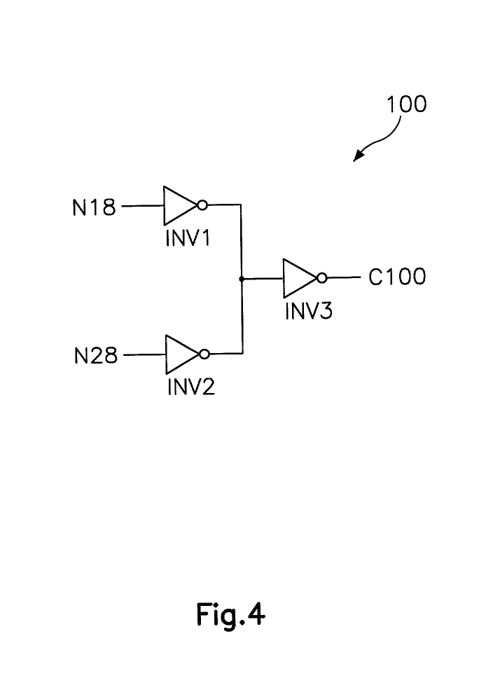

FIG. 4 is a detailed circuit diagram illustrating the clock synthesizing unit 100.

As illustrated in FIG. 4, the clock synthesizing unit 100 includes: inverters INV1 and INV2 for respectively driving the clock signals of the corresponding nodes N18 and N28; and an inverter INV3 for synthesizing and driving phases of the output signals from the inverters INV1 and INV2.

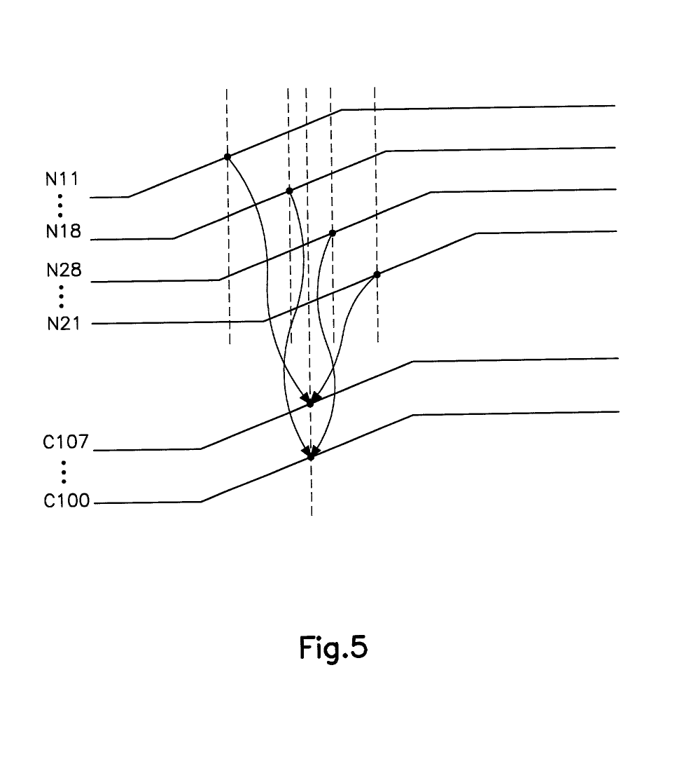

The operation of the data I/O circuit of the semiconductor memory device in accordance with the first embodiment of the present invention will now be described with reference to FIG. 5.

The clock synchronization unit 10 synchronizes the internal clock signal ICLK with the external clock signal ECLK.

The internal clock signal ICLK driven by the clock driving unit 20 is transmitted to the data buffers DBUF100-DBUF115 through the clock signal transmission line CL. The clock signal transmission line CL is connected to the plurality of clock synthesizing units 100˜115.

The clock synthesizing units 100-115 receive the internal clock signals of the corresponding nodes and synthesize phases of the internal clock signals. The clock synthesizing units 100˜115 output the synthesized clock signals to the data buffers DBUF100-DBUF115.

That is, the clock signals N18 and N28 shown in FIG. 5 are inputted to the inverters INV1 and INV2 of the clock synthesizing unit 100 shown in FIG. 4. The clock signals N18 and N28 are driven in the inverters INV1 and INV2, and inputted to the inverter INV3. Referring to FIG. 5, the clock synthesizing unit 100 generates a clock signal C100 having an intermediate value of time differences of the inputted clock signals.

In the same manner, the clock synthesizing unit 107 generates a clock signal C107 having an intermediate value of time differences of the clock signals of the corresponding nodes N11 and N21.

In addition, the other clock synthesizing units 101-106 and 108-115 respectively generate clock signals having intermediate values of time differences of the clock signals of the corresponding nodes.

Accordingly, all the data buffers DBUF100-DBUF115 have an identical data output time.

At this time, the clock signal transmission line CL is symmetrically connected from the clock driving unit 20. Both parts of the clock signal transmission line CL consist of an identical metal line and have an identical length in the same conditions. Therefore, the data buffers DBUF100-DBUF107 and the data buffers DBUF108-DBUF115 which are symmetrically aligned have the same data output time.

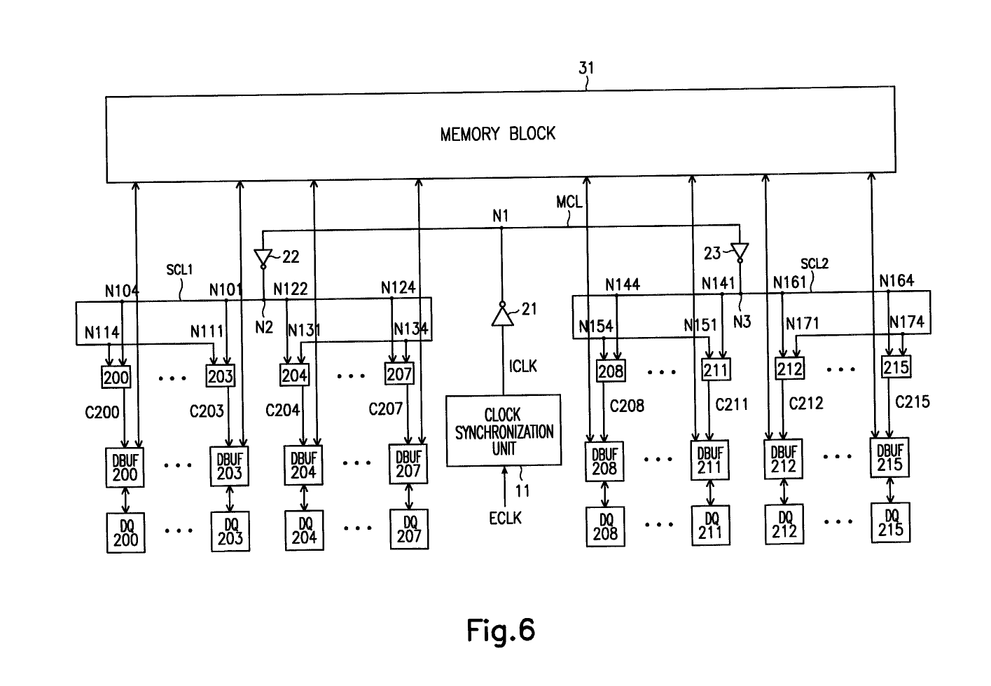

FIG. 6 is a block diagram illustrating a data I/O circuit of a semiconductor memory device in accordance with a second embodiment of the present invention.

As shown in FIG. 6, the data I/O circuit of the semiconductor memory device includes a clock synchronization unit 11, a main clock driving unit 21, a plurality of sub clock driving units 22 and 23, a plurality of clock synthesizing units 200˜215, a plurality of data buffers DBUF 200˜DBUF215 and a plurality of data pads DQ200˜DQ215. The clock synchronization unit 11 synchronizes an internal clock signal ICLK with an external clock signal ECLK. The main clock driving unit 21 transfers the internal clock signal ICLK to a main clock signal transmission line MCL. The plurality of sub clock driving units 22 and 23 drive the internal clock signals transmitted to the main clock signal transmission line MCL and re-transferring the driven clock signals to a sub clock signal transmission line. The plurality of clock synthesizing units 200˜215 synthesizes clock signals of corresponding nodes in the sub clock signal transmission line. The plurality of data buffers DBUF200˜DBUF215 buffer data according to the clock signals C200˜C215 from the plurality of clock synthesizing units 200˜215. The plurality of data pads DQ200˜DQ215 externally output the data from the plurality of data buffers DBUF200˜DBUF215, or externally receiving data.

The data buffers DBUF200-DBUF207 and the data buffers DBUF208-DBUF215 are symmetrically aligned with respect to the clock driving unit 21. The sub clock driving units 22 and 23 are aligned at the center portions of the data buffers DBUF200-DBUF207 and the data buffers DBUF208-DBUF215, for transmitting the internal clock signal ICLK driven by the main clock driving unit 21 to the sub clock signal transmission lines SCL1 and SCL2.

The operation of the data I/O circuit of the semiconductor memory device in accordance with the second embodiment of the present invention will now be described.

The clock synchronization unit 11 synchronizes the external clock signal ECLK, thereby outputting the internal clock signal ICLK.

The main clock driving unit 21 drives the internal clock signal ICLK, and transmits the driven internal clock signal ICLK to the main clock signal transmission line MCL.

The sub clock driving units 22 and 23 drive the clock signals transmitted to the main clock signal transmission line MCL, and transmit the driven clock signals to the sub clock signal transmission lines SCL1 and SCL2, respectively. Here, the sub clock signal transmission line SCL1 is connected to both ends of the data buffers DBUF200-DBUF207, and extended to the node N1 to which the sub clock driving unit 22 is connected. In the same manner, the sub clock signal transmission line SCL2 is connected to both ends of the data buffers DBUF208-DBUF215, and extended to the node N2 to which the sub clock driving unit 23 is connected.

The clock synthesizing units 200-215 receive the clock signals of the corresponding nodes N101-N174 of the sub clock signal transmission lines SCL1 and SCL2, synthesize the phases of the clock signals, and output the resultant clock signals to the data buffers DBUF200-DBUF215, respectively.

Accordingly, the phases of the clock signals C200-C215 synthesized by the clock synthesizing units 200-215 are equalized, and thus the clock signals C200-C215 do not have a time difference.

The succeeding operations of the second embodiment are identical to the above-described operations of the first embodiment, and therefore detailed explanations thereof are omitted.

As discussed earlier, in accordance with the present invention, the clock synthesizing units equalize the phases of the clock signals so as to reduce the time difference of the clock signals generated in the clock signal transmission line according to position of the data buffers. Therefore, the data buffers have an identical enable time, thereby decreasing the data setup/hold time. As a result, it is possible to operate the semiconductor memory device at a high speed.

As the present invention may be embodied in several forms without departing from the spirit or essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the meets and bounds of the claims, or equivalences of such meets and bounds are therefore intended to be embraced by the appended claims.

What is claimed is:

1. A data I/O circuit of a semiconductor memory device, the data I/O circuit comprising:
a clock synchronization means for synchronizing an internal clock signal with an external clock signal;
a clock signal transmission line having nodes;
a clock driving means for transferring the internal clock signal to the clock signal transmission line;
a plurality of clock synthesizing means for synthesizing the internal clock signals of corresponding nodes in the clock signal transmission line;
a plurality of data buffers for buffering data according to the synthesized clock signals from the plurality of clock synthesizing means; and
a plurality of data pads for externally outputting the data from the plurality of data buffers, or receiving data from external devices.

2. The data I/O circuit according to claim 1, wherein the clock signal transmission line is connected to the clock driving means, extended to both ends of the plurality of data buffers, and extended from both ends to a node to which the clock driving means is connected.

3. The data I/O circuit according to claim 2, wherein the clock synthesizing means synthesizes a phase of a clock signal of the closest node of the clock signal transmission line connected from the clock driving means to both ends of the plurality of data buffers, and a phase of a clock signal of the closest node of the clock signal transmission line connected from both ends of the plurality of data buffers to the clock driving means.

4. The data I/O circuit according to claim 1, wherein the clock synthesizing means comprises:
a first driving means for driving a clock signal of the closest node of the clock signal transmission line connected from the clock driving means to both ends of the plurality of data buffers;
a second driving means for driving a clock signal of the closest node of the clock signal transmission line connected from both ends of the plurality of data buffers to the clock driving means; and
a phase synthesizing means for synthesizing phases of the output signals from the first and second driving means.

5. A data I/O circuit of a semiconductor memory device, comprising:
a clock synchronization means for synchronizing an internal clock signal with an external clock signal;
a main clock signal transmission line;
a main clock driving means for transferring the internal clock signal to the main clock signal transmission line;
a sub clock signal transmission line having nodes;
a plurality of sub clock driving means for driving the internal clock signals transmitted to the main clock signal transmission line and re-transferring the driven clock signals to the sub clock signal transmission line;
a plurality of clock synthesizing means for synthesizing clock signals of corresponding nodes in the sub clock signal transmission line;
a plurality of data buffers for buffering data according to the clock signals from the plurality of clock synthesizing units; and
a plurality of data pads for externally outputting the data from the plurality of data buffers, or externally receiving data.

6. The data I/O circuit according to claim 5, wherein the sub clock signal transmission line is extended to both ends of a predetermined number of data buffers among the plurality of data buffers, and extended from both ends to a node to which the sub clock driving means is connected.

7. The data I/O circuit according to claim 6, wherein the clock synthesizing means synthesizes a phase of a clock signal of the closest node of the sub clock signal transmission line connected from the sub clock driving means to both ends of the predetermined number of data buffers, and a phase of a clock signal of the closest node of the sub clock signal transmission line connected from both ends of the predetermined number of data buffers to the sub clock driving means.

8. The data I/O circuit according to claim 6, wherein the clock synthesizing means comprises:
a first driving means for driving a clock signal of the closest node of the sub clock signal transmission line connected from the sub clock driving means to both ends of the predetermined number of data buffers;
a second driving means for driving a clock signal of the closest node of the sub clock signal transmission line connected from both ends of the predetermined number of data buffers to the sub clock driving means; and
a phase synthesizing means for synthesizing phases of the output signals from the first and second driving means.
